(19) United States
(12) Patent Application Publication
(10) Pub. No.: US 2026/0096163 A1
(43) Pub. Date: Apr. 2, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Ming-Han LIAO, Hsinchu (TW); Po-Hsien CHENG, Hsinchu (TW); KENG-CHU LIN, Hsinchu (TW); Pinyen LIN, Hsinchu (TW); CHIH-HAO WANG, Hsinchu (TW); Min CAO, Hsinchu (TW)

(73) Assignee: Taiwan Semiconductor Manufacturing Company, Ltd., Hsinchu (TW)

(21) Appl. No.: 18/899,947

(22) Filed: Sep. 27, 2024

(51) Int. Cl. H01L 29/08; H01L 29/06; H01L 29/423; H01L 29/66; H01L 29/775

(52) U.S. Cl. CPC H10D 62/151; H10D 30/014; H10D 30/43; H10D 30/6735; H10D 62/121; H10D 64/017

(57) ABSTRACT

A semiconductor device includes a first epitaxial source/drain feature, a second epitaxial source/drain feature, two or more semiconductor layers and at least one dielectric spacer. The two or more semiconductor layers are electrically connected between the first epitaxial source/drain feature and the second epitaxial source/drain feature. The dielectric spacer is located between the two or more semiconductor layers, the dielectric spacer surrounds two opposite sides of the first epitaxial source/drain feature and the second epitaxial source/drain feature, and an interface between the dielectric spacer and each of the two opposite sides is a plane.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-11 are perspective views of various stages for manufacturing a semiconductor device according to embodiments of the present disclosure.

FIG. 12 is a schematic diagram of a dielectric spacer according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure can pattern a gate all around (GAA) transistor structure by any suitable method. For example, one or more photolithography processes may be used to pattern the structure, including dual patterning processes or multiple patterning processes. Typically, a dual or multi-patterning process combines a photolithography process with a self-aligned process, allowing the creation of patterns with, for example, smaller pitches than achievable using a single direct photolithography process. For example, in one embodiment, inner spacers are formed in the cavity after the dummy semiconductor layers are removed.

The present disclosure relates to semiconductor devices and methods of manufacturing the same. More specifically, some embodiments of the present disclosure relate to semiconductor devices including improved inner spacers. The semiconductor devices proposed herein include p-type semiconductor devices or n-type semiconductor devices. Additionally, a semiconductor device may have one or more channel regions (e.g., nanowires) associated with a single continuous gate structure, or multiple gate structures. A person having ordinary skills may recognize other examples of semiconductor devices that may benefit from aspects of the present disclosure.

While the embodiments of this disclosure are discussed with respect to nanostructure channel FETs (e.g., Horizontal Gate All Around (HGAA) FETs, Vertical Gate All Around (VGAA) FETs, nanosheet/nanowire FET, nano-ribbon FET, Multi-Bridge-Channel FET), implementations of some aspects of the present disclosure may be used in other processes and/or in other devices, such as planar FETs, Fin-FETs, and other suitable devices. A person having ordinary skills in the art will readily understand other modifications that may be made are contemplated within the scope of this disclosure.

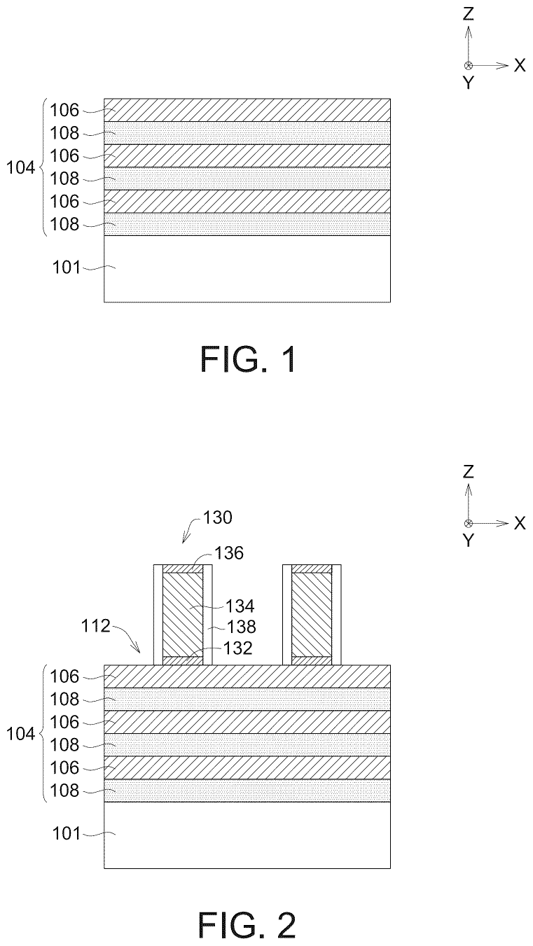

FIGS. 1-11 are perspective views of various stages for manufacturing a semiconductor device 100 according to embodiments of the present disclosure. It will be appreciated that for additional embodiments of the method, additional steps may be provided before, during, and after the processes illustrated in FIGS. 1-11, and some of the steps described below may be replaced or eliminated. The sequence of steps/processes is unrestricted and interchangeable.

As shown in FIG. 1, semiconductor device 100 includes a stack of semiconductor layers 104 formed over a substrate 101. The substrate 101 may be a semiconductor substrate. The substrate 101 may include single crystal semiconductor materials such as, but not limited to, silicon (Si), germanium (Ge), silicon germanium (SiGe), gallium arsenide (GaAs), indium antimonide (InSb), gallium phosphide (GaP), Gallium antimonide (GaSb), indium aluminum arsenide (InAlAs), indium gallium arsenide (InGaAs), gallium antimony phosphide (GaSbP), gallium arsenide antimonide (GaAsSb) and indium phosphide (InP). In some embodiments, the substrate 101 is a silicon-on-insulator (SOI) substrate having an insulating layer (not shown) disposed between two silicon layers for reinforcement. In one aspect, the insulating layer is an oxygen-containing layer.

The stack of semiconductor layers 104 includes semiconductor layers made of different materials to facilitate the formation of nanostructured channels in multi-gate devices such as nanostructured field effect transistors. In some embodiments, the stack of semiconductor layers 104 includes a plurality of first semiconductor layers 106 and a plurality of second semiconductor layers 108 (also referred to as dummy layers). In some embodiments, the stack of semiconductor layers 104 includes alternating first semiconductor layers 106 and second semiconductor layers 108, and the first semiconductor layers 106 and the second semiconductor layers 108 are disposed parallel to each other. The first semiconductor layer 106 and the second semiconductor layer 108 are made of semiconductor materials with different etching selectivities and/or different oxidation rates. For example, the first semiconductor layer 106 can be made of Si, and the second semiconductor layer 108 can be made of SiGe. In some examples, first semiconductor layer 106 may be made of germanium-doped silicon, and second semiconductor layer 108 may be made of SiGe. In some examples, first semiconductor layer 106 can be made of SiGe and second semiconductor layer 108 can be made of Si. In some embodiments, the first semiconductor layer 106 can be made of SiGe having a first germanium concentration range, and the second semiconductor layer 108 can be made of SiGe having a second germanium concentration range that is lower or greater than the first germanium concentration range. Alternatively, in some embodiments, any one of the first semiconductor layer 106 and the second semiconductor layer 108 may be or include other materials, such as Ge, SiC, GeAs, GaP, InP, InAs, InSb, GaAsP, AlInAs, AlGaAs, InGaAs, GaInP, GaInAsP or any combination thereof. In some embodiments, the second semiconductor layers 108 may be crystal-oxide, such as HfO₂, ZrO₂, ZnO₂, MgO, IGZO, Y₂O₃ and beta-SiN.

The thickness of the first semiconductor layer 106 and the second semiconductor layer 108 may vary depending on application and/or device performance considerations. In some embodiments, each of the first semiconductor layer 106 and the second semiconductor layer 108 has a thickness between about 5 nm and about 30 nm. In other embodiments, each of the first semiconductor layer 106 and the second semiconductor layer 108 has a thickness between about 10 nm and about 20 nm. In some embodiments, each of the first semiconductor layer 106 and the second semiconductor layer 108 has a thickness between about 6 nm and about 12 nm. Each second semiconductor layer 108 may have a thickness equal to, smaller than, or larger than that of the first semiconductor layer 106. The second semiconductor layer 108 may eventually be removed and used to define the vertical distance between adjacent channels of the semiconductor device structure 100.

The first semiconductor layer 106 or a portion thereof may form the nanostructured channels of the semiconductor device 100 in a later manufacturing stage. The term “nanostructure” is used herein to mean any portion of a material that has a nanometer or even micron dimension and has an elongated shape, regardless of the cross-sectional shape of the portion. Accordingly, this term refers to elongated material portions and bundled or rod-like material portions of circular and substantially circular cross-sections, including, for example, cylindrical or substantially rectangular cross-sections. The nanostructure channels of the semiconductor device 100 may be surrounded by gate electrodes. Semiconductor device 100 may include nanostructured transistors. Nanostructured transistors can be called nanowire transistors, gate-all-around transistors, multi-bridge channel (MBC) transistors, or any transistor with a gate electrode surrounding a channel. The use of first semiconductor layer 106 to define one or more channels of semiconductor device 100 is discussed further below.

The first semiconductor layer 106 and the second semiconductor layer 108 are formed by any suitable deposition process, such as an epitaxial process. For example, the stack of semiconductor layers 104 may be epitaxially grown by a molecular beam epitaxy (MBE) process, a metalorganic chemical vapor deposition (MOCVD) process, and/or other suitable epitaxy processes. crystal growth process. Although the three first semiconductor layers 106 and the three second semiconductor layers 108 are alternately stacked as shown in FIG. 1, it should be understood that according to the predetermined number of nanostructure channels of each field effect transistor, a stack of the semiconductor layer 104 can be any number of first semiconductor layers 106 and second semiconductor layers 108. For example, the number of first semiconductor layers 106 (i.e., the number of channels) may be between 2 and 8.

In some embodiments, a hard mask layer (not shown) formed on the stack of semiconductor layers 104 is patterned using multiple patterning steps including photolithography and etching processes. The etching process may include dry etching, wet etching, reactive ion etching (RIE) and/or other suitable processes. The photolithography process may include forming a photoresist layer (not shown) over the hard mask layer, exposing the photoresist layer to the pattern, performing a post-exposure bake process, and developing the photoresist layer to form a masking element of the photoresist layer. In some embodiments, an electron beam (e-beam) lithography process may be used to pattern the photoresist layer to form the masking element. The etching process creates trenches in the unprotected areas through the hard mask layer, through the stack of semiconductor layers 104 and into the substrate 101, leaving a plurality of vertically extending fin structures. The groove extends along the X direction. The trenches may be etched using dry etching (e.g., RIE), wet etching, and/or combinations thereof.

In FIG. 2, one or more sacrificial gate structures 130 are formed above the vertically extending fin structure 112. The sacrificial gate structure 130 may be formed over a portion of the fin structure 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 can be formed by sequentially depositing a blanket layer of the sacrificial gate dielectric layer 132, the sacrificial gate electrode layer 134, and the mask layer 136, and then these layers are patterned into a sacrificial gate structure 130. The gate spacers 138 are then formed on the sidewalls of the sacrificial gate structure 130. For example, the gate spacers 138 may be formed by conformally depositing one or more layers of gate spacers 138 and anisotropically etching the one or more layers. Although one sacrificial gate structure 130 is shown in the figures, in some embodiments, two or more sacrificial gate structures 130 may be configured along the X direction.

The sacrificial gate dielectric layer 132 may include one or more layers of dielectric material, such as a silicon oxide-based material. The sacrificial gate electrode layer 134 may include silicon, such as polycrystalline silicon or amorphous silicon. The mask layer 136 may include more than one layer, such as an oxide layer and a nitride layer. The gate spacer 138 may be made of a dielectric material, such as silicon oxide, silicon nitride, silicon carbide, silicon oxynitride (SiON), silicon nitride carbide (SiCN), silicon oxycarbide (SiCO), silicon oxynitride oxide (SiOCN) and/or combinations thereof.

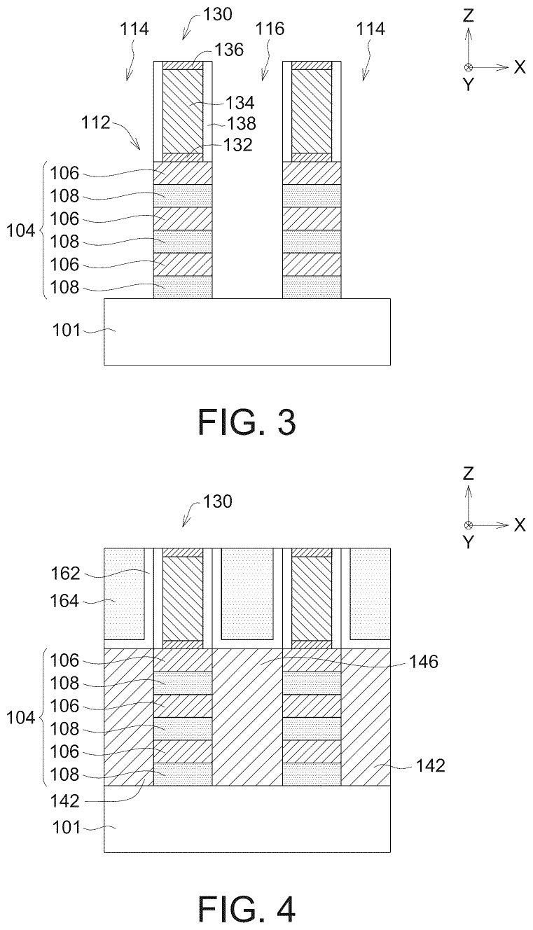

In FIG. 3, by removing the portion of the fin structure 112 that is not covered by the sacrificial gate structure 130, the two opposite sides of the first semiconductor layer 106 and the second semiconductor layer 108 are exposed. The first semiconductor layer 106 covered by the sacrificial gate electrode layer 134 of the sacrificial gate structure 130 serves as a channel region of the semiconductor device 100. Trenches that are exposed to opposite sides of the sacrificial gate structure 130 define source/drain (S/D) regions 114 and 116 of the semiconductor device 100. In some cases, some source/drain regions 114 and 116 may be shared between various transistors. For example, each of the source/drain regions 114 and 116 may be connected together and implemented as a multifunctional transistor. The trenches can be completed by an etching process, which can be dry etching or wet etching such as RIE, NBE or the like, such as using tetramethylammonium hydroxide (TMAH), ammonium hydroxide (NH₄OH) or any suitable etchant.

It is worth noting that the inner wall of the trench is a straight surface, that is to say, the side surfaces of the first semiconductor layer 106 and the second semiconductor layer 108 are straight surfaces, and there is no need to perform any selective etching on the second semiconductor layer 108 and formation of inner spacers thereon, so the epitaxial growth rate is consistent and the epitaxial quality is better during the subsequent epitaxial process, and thus dislocation lines caused by the traditional uneven epitaxial growth due to the uneven interface of the inner spacers during the epitaxial growth process are reduced.

Referring to FIG. 4, in subsequent processes, epitaxial source/drain features 142 and 146 are formed in the source/drain regions 114 and 116. The epitaxial source/drain features 142 and 146 may be made of one or more layers of Si, SiP, SiC, and SiCP for n-channel FETs, or Si, SiGe, Ge for p-type channel FETs. For p-type channel FETs, p-type dopants such as boron may also be included in the epitaxial source/drain features 142 and 146. The epitaxial source/drain features 142 and 146 may be formed by epitaxial growth methods using chemical vapor deposition, atomic layer deposition, or molecular beam epitaxy. Epitaxial source/drain features 142 and 146 may be grown vertically and horizontally to form facets, which may correspond to crystallographic planes of the material used for the substrate 101. In some cases, the epitaxial source/drain features 142 and 146 may be grown and merged with adjacent epitaxial source/drain features 142 and 146. In some embodiments, prior to forming the epitaxial source/drain features 142 and 146, a source/drain pre-clean process may be performed to remove native oxide layers on the first semiconductor layers 106 and/or the second semiconductor layers 108. The source/drain pre-cleaning process may be an inert gas sputtering process (e.g., argon sputtering) or a plasma-based cleaning process. In one embodiment, the source/drain pre-clean process is a Siconi™ process that uses remote plasma to generate ammonium fluoride (NH₄F) etchant from nitrogen trifluoride (NF₃) and ammonia (NH₃) to minimize damage to semiconductor device 100.

In one example shown in FIG. 4, one of a pair of epitaxial source/drain features 142 and 146 disposed on one side of the sacrificial gate structure 130 is designated as the source feature (source terminal), and the other of the pair of epitaxial source/drain features 142 and 146 disposed on the other side of the sacrificial gate structure 130 is designated as the drain feature (the drain terminal). The source feature (source terminal) and the drain feature (drain terminal) are connected by a channel layer (e.g., first semiconductor layer 106). The epitaxial source/drain features 142 and 146 contact the first semiconductor layer 106 beneath the sacrificial gate structure 130. In some cases, the epitaxial source/drain features 142 and 146 may grow beyond the topmost semiconductor channel (i.e., the topmost first semiconductor layer 106 below the sacrificial gate structure 130) to contact the gate spacer 138.

In some embodiments, a contact etch stop layer (CESL) 162 is conformally formed on the exposed surface of the semiconductor device 100. The contact etch stop layer 162 covers the sidewalls of sacrificial gate structure 130 and the upper surfaces of epitaxial source/drain features 142 and 146. The contact etch stop layer 162 may include an oxygen-containing material or a nitrogen-containing material, such as silicon nitride, silicon carbonitride, silicon oxynitride, silicon carbonitride, silicon oxide, silicon oxycarbide, the like, or combinations thereof, and may formed by CVD, PECVD, ALD or any suitable deposition technique. Next, a first interlayer dielectric (ILD) layer 164 is formed on the contact etch stop layer 162 above the semiconductor device 100. The material of the first interlayer dielectric layer 164 may include compounds including Si, O, C, and/or H, such as silicon oxide, ethyl orthosilicate oxide, SiCOH, and SiOC. Organic materials such as polymers may also be used for the first interlayer dielectric layer 164. The first interlayer dielectric layer 164 may be deposited by a PECVD process or other suitable deposition techniques. In some embodiments, after forming the first interlayer dielectric layer 164, the semiconductor device 100 may undergo a thermal process to anneal the first interlayer dielectric layer 164.

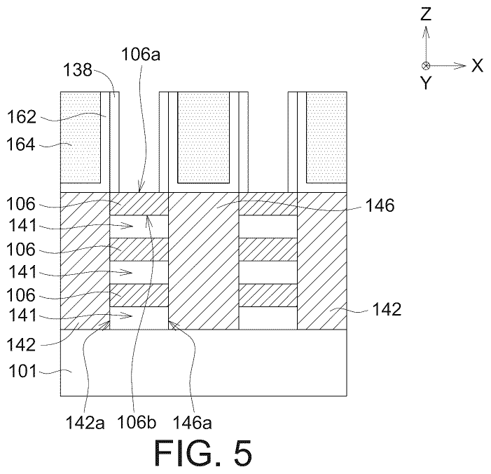

In FIG. 5, the sacrificial gate electrode layer 134 is removed by performing any suitable process, such as dry etching, wet etching, or a combination thereof. In some embodiments, a wet etchant such as a tetramethylammonium hydroxide solution may be used to selectively remove the sacrificial gate electrode layer 134 but not the gate spacer 138 or the first interlayer dielectric layer 164 and contact etch stop layer 162. In addition, each second semiconductor layer 108 of the stack of semiconductor layers 104 is then removed to form a cavity 141. In some embodiments, the second semiconductor layer 108 is removed through a selective wet etching process. In the case where the second semiconductor layer 108 is made of SiGe and the first semiconductor layer 106 is made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP) or potassium hydroxide (KOH) solutions to expose the upper and lower surfaces of the first semiconductor layers 106.

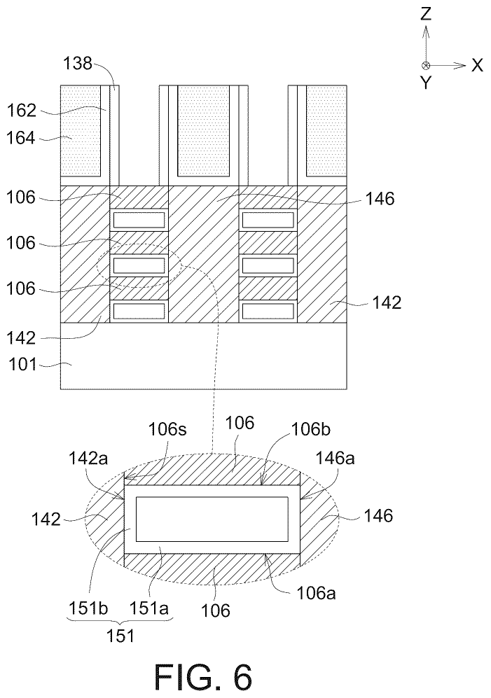

In FIGS. 6 to 9, after removing the second semiconductor layers 108, a dielectric layer is deposited in the cavities 141 to form dielectric spacers 144 (or so-called inner spacers). The dielectric spacers 144 may be made of a low-k dielectric material, such as SiON, SiCN, SiOC, SiOCN, or SiN. In some embodiments, dielectric spacers 144 are formed from a material having a dielectric constant in the range of 3.5 to 5.5. The dielectric spacers 144 may be formed by atomic layer deposition, pulsed plasma chemical vapor deposition, or any suitable deposition process. The end portion of the dielectric spacer 144 between the first semiconductor layers 106 may have a flat surface 144f that is substantially coplanar with the outer surface 106s of the first semiconductor layer 106.

In some embodiments, the dielectric spacer is, for example, an oxygen-containing silicon material, wherein the silicon content is between about 25% and about 40%. In some embodiments, the dielectric spacer is, for example, a silicon material containing oxygen and carbon, the silicon content is between about 25% and about 35%, and the carbon content is between 0.1 and 15%.

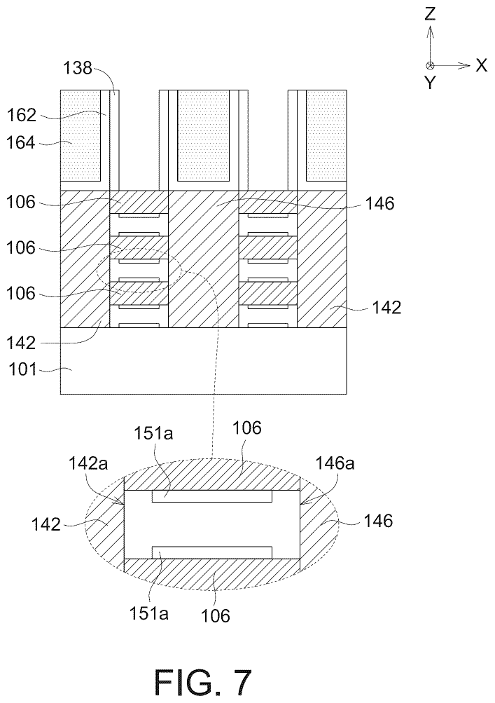

The formation method of the dielectric spacer 144 is as follows. Referring to FIG. 6, an inhibitor material layer 151 is formed in the cavity 141. The inhibitor material layer 151 covers the upper surface 106a and the lower surface 106b of each of the first semiconductor layers 106 and opposite sides 142a and 146a of the epitaxial source/drain features 142 and 146. The inhibitor material layer 151 is deposited, for example, by a chemical deposition process or a physical deposition process. In FIG. 6, the deposition of the inhibitor material layer 151 on the first semiconductor layer 106 has a high selectivity (e.g., greater than 5) relative to the deposition of the inhibitor material layer 151 on the epitaxial source/drain features 142 and 146, so that the amount of inhibitor material layer 151 deposited on first semiconductor layer 106 (refer to the first portion 151a) is greater than the amount of inhibitor material layer 151 deposited on epitaxial source/drain features 142 and 146 (refer to second portion 151b). In other words, the inhibitor material layer 151 is relatively easy to adhere to the first semiconductor layers 106 than the epitaxial source/drain features 142 and 146. In FIG. 7, the inhibitor material layer 151 is etched to remove the second portion 151b of the inhibitor material layer 151 less deposited on the epitaxial source/drain features 142 and 146, but the first portion 151a of the inhibitor material layer 151 more deposited on the first semiconductor layers 106 is not removed completely, that is, a thickness of the first portion 151a of the inhibitor material layer 151 on the first semiconductor layers 106 is greater than a thickness of the second portion 151b of the inhibitor material layer 151 on the epitaxial source/drain features 142 and 146, so that only the residual first portion 151a can be remained on the first semiconductor layers 106.

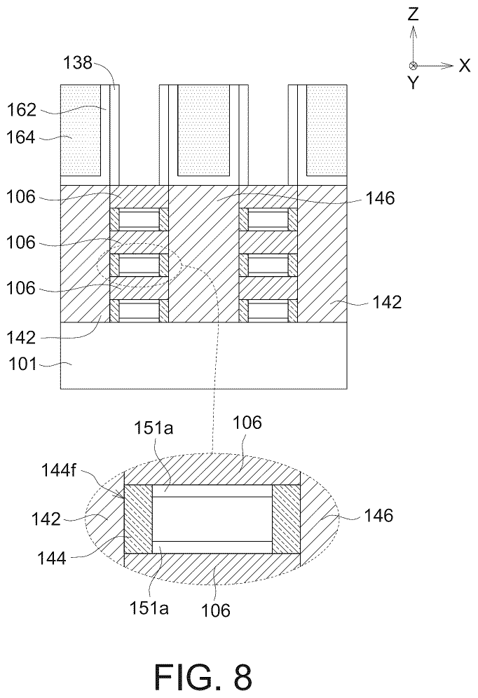

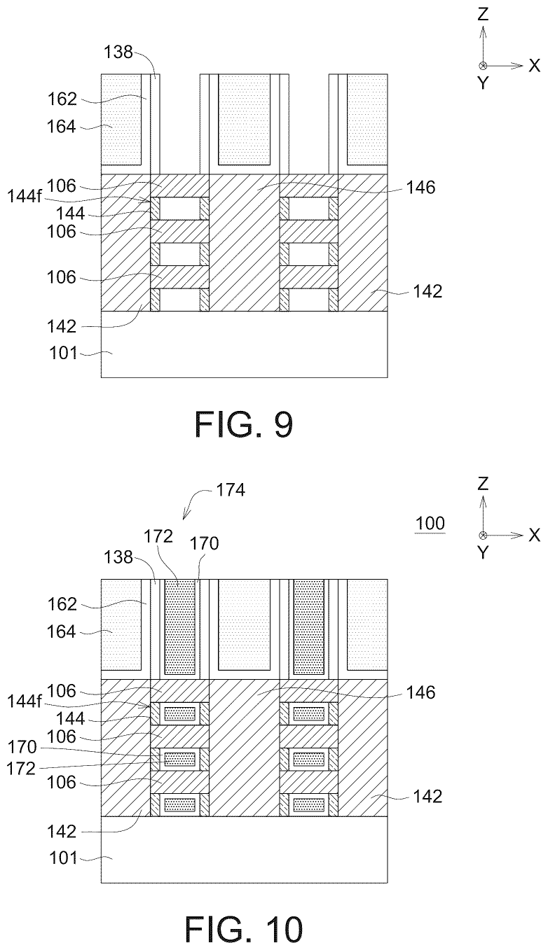

In FIG. 8, the dielectric spacers 144 are formed only on opposing sides 142a and 146b of the epitaxial source/drain features 142 and 146, but not on the surfaces of the first semiconductor layers 106 covered by the inhibitor material layer 151. In FIG. 9, the inhibitor material layer 151 is removed to expose the surfaces of the first semiconductor layers 106. In some embodiments, the inhibitor material layer 151 may be formed of organic compounds, such as 3-Aminopropyl triethoxysilane (APTES), α-bromoisobutyryl bromide (BIBB), Polymethylmethacrylate (PMMA), or combinations thereof. The etchant is H₂O₂, for example. The dielectric spacers 144 may be formed by using techniques such as thermal oxidation or deposited by CVD, ALD, or the like.

In some embodiments, the dielectric spacers 144 may be made of a low-k dielectric material with a dielectric constant of 3.6-3.8, such as SiOC. Low-k methylene-bridged silicon oxycarbide (SiOC) thin film can be selectively deposited on opposing sides 142a and 146b of the epitaxial source/drain features 142 and 146 by using bis(trichlorosilyl)-methane and water as a precursor and coreactant, respectively, please refer to the reaction formula (1) as follows.

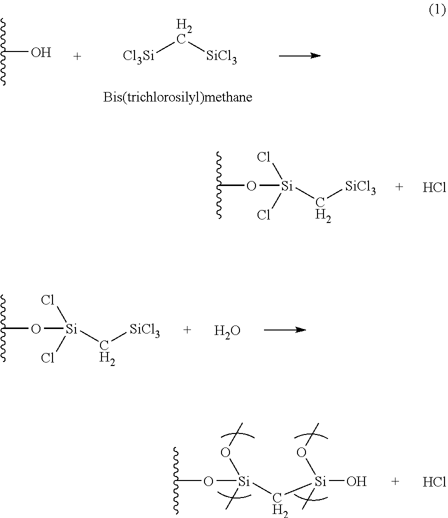

In FIG. 10, after the dielectric spacers 144 are formed, the gate dielectric layer 170 is formed to surround the first semiconductor layer 106, and the gate electrode layer 172 is formed on the gate dielectric layer 170. The gate dielectric layer 170 and the gate electrode layer 172 may be collectively referred to as the gate structure 174. In some embodiments, an interface layer (IL) (not shown) is formed between the gate dielectric layer 170 and the exposed surface of the first semiconductor layer 106. In such cases, the interface layer may also be formed on the well portion of the substrate 101. The interface layer may include or be made of oxygen-containing materials or silicon-containing materials, such as silicon oxide, silicon oxynitride, oxynitride, hafnium silicate, and the like. The interface layer can be formed by CVD, ALD, cleaning process or any suitable process. In some embodiments, gate dielectric layer 170 includes one or more layers of dielectric materials, such as silicon oxide, silicon nitride, high-k dielectric materials, other suitable dielectric materials, and/or combinations thereof. Examples of high-k dielectric materials include HfO₂, HfSiO, HfSiON, HfTaO, HfTIO, HfZrO, zirconium oxide, alumina, titanium oxide, hafnium dioxide-aluminum oxide (HfO₂—Al₂O₃) alloy, and other suitable high-k dielectric materials Constant dielectric materials and/or combinations thereof. Gate dielectric layer 170 may be formed by CVD, ALD, or any suitable deposition technique.

The gate electrode layer 172 may include one or more layers of conductive materials, such as polycrystalline silicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials and/or any combination thereof. The gate electrode layer 172 may be formed by CVD, ALD, electroplating or other suitable deposition techniques. The gate electrode layer 172 may also be deposited over the upper surface of the first interlayer dielectric layer. Next, the gate dielectric layer 170 and the gate electrode layer 172 formed over the first interlayer dielectric layer are removed by using, for example, chemical mechanical polishing until the top surface of the first interlayer dielectric layer is exposed.

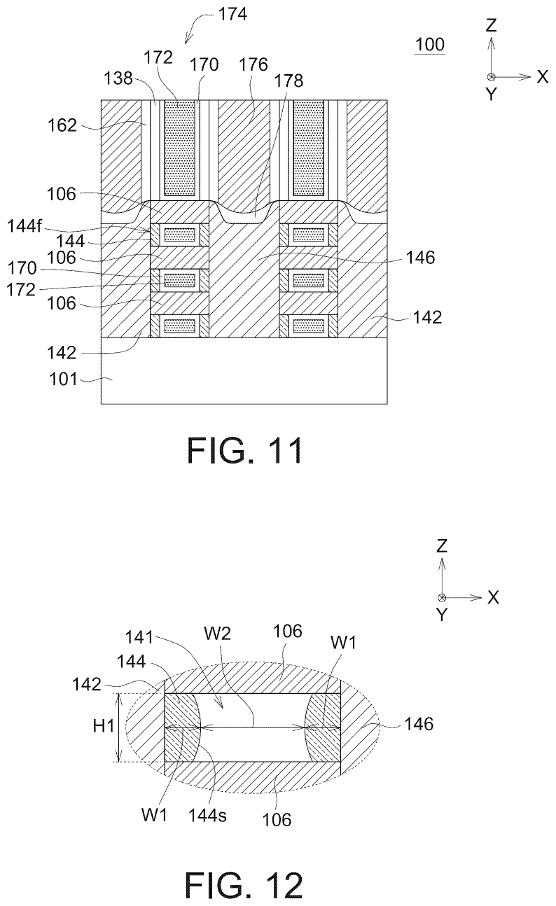

In FIG. 11, the source/drain contacts 176 are formed in the first interlayer dielectric layer 162. Prior to forming the source/drain contacts 176, contact openings are formed in the first interlayer dielectric layer 162 to expose the epitaxial source/drain features 142 and 146. Contact openings are formed through various layers, including first interlayer dielectric layer 162 and contact etch stop layer 162, using suitable photolithography and etching techniques to expose epitaxial source/drain features 142 and 146. In some embodiments, upper portions of the epitaxial source/drain features 142 and 146 are etched.

After forming the contact openings, a silicide layer 178 is formed over the epitaxial source/drain features 142 and 146. The silicide layer 178 electrically couples epitaxial source/drain features 142 and 146 to subsequently formed source/drain contacts 176. The silicide layer 178 may be formed by depositing a metal source layer over epitaxial source/drain features 142 and 146 and performing a rapid thermal annealing process. During the rapid anneal process, a portion of the metal source layer over the epitaxial source/drain features 142 and 146 reacts with the silicon in the epitaxial source/drain features 142 and 146 to form a silicide layer 178. Next, the unreacted portion of the metal source layer is removed. In some embodiments, silicide layer 178 is made of metal or metal alloy silicide, and the metal includes noble metals, refractory metals, rare earth metals, alloys thereof, or combinations thereof. Next, conductive material is formed in the contact openings and source/drain contacts 176 are formed. The conductive material may be made of materials including one or more of Ru, Mo, Co, Ni, W, Ti, Ta, Cu, Al, TiN, and TaN. Although not shown, prior to forming the source/drain contacts 176, a barrier layer (e.g., TiN, TaN, or the like) may be formed on the sidewalls of the contact openings. Next, a planarization process such as chemical mechanical polishing is performed to remove excess deposited contact material and expose the top surface of the gate electrode layer 172.

It should be understood that the semiconductor device 100 may undergo further complementary metal oxide semiconductor (CMOS) processes and/or back-end-of-line (BEOL) processes to form various features, such as transistors, contacts/vias, interconnect metal layers, dielectric layers, passivation layers, etc. The semiconductor device 100 may also include backside source/drain contacts on the backside of substrate 101 such that the sources or drains of epitaxial source/drain features 142 and 146 are connected to the backside power rail (for example, positive voltage VDD or negative voltage VSS) via the backside source/drain contacts.

Referring to FIG. 12, a schematic diagram of a dielectric spacer according to an embodiment of the present disclosure is illustrated. The dielectric spacers 144 are formed on opposite sides of a cavity 141, and the dielectric spacers 144 protrude horizontally from the opposite sides of the cavity 141 toward the middle to have a convex profile 144s. The distance W1 from the top to the bottom of the convex profile 144s is about 2 to 10 nm, the vertical height H1 of the cavity 141 is about 3 to 10 nm, and the remaining horizontal width W2 inside the cavity 141 after the dielectric spacers 144 is deposited is about 5 to 30 nm. This convex profile 144s can increase the distance between the gate electrode layer 172 and each of the epitaxial source/drain features 142 and 146 to reduce the parasitic capacitance between the gate electrode layer 172 and the epitaxial source/drain features 142 and 146.

The present disclosure is directed to a semiconductor device and a manufacturing method thereof with a less dislocation line in source and drain epitaxy and a higher channel stress in the nanosheet structure. During the formation of the source and drain epitaxy, uniform flat interface is formed between semiconductor layers and the source and drain epitaxy without the non-uniform inner spacers, and leads to the better quality of epitaxy growth. Therefore, the traditional inner spacer process leading to the poor epitaxy and less channel stress in the nanosheet structure can be improved.

According to some embodiments of the present disclosure, a semiconductor device includes a first epitaxial source/drain feature, a second epitaxial source/drain feature, two or more semiconductor layers and at least one dielectric spacer. The two or more semiconductor layers are electrically connected between the first epitaxial source/drain feature and the second epitaxial source/drain feature. The dielectric spacer is located between the two or more semiconductor layers, the dielectric spacer surrounds two opposite sides of the first epitaxial source/drain feature and the second epitaxial source/drain feature, and an interface between the dielectric spacer and each of the two opposite sides is a plane.

According to some embodiments of the present disclosure, a method of manufacturing a semiconductor device is provided as follows. A first epitaxial source/drain feature is formed over a substrate. A second epitaxial source/drain feature is formed over the substrate. Two or more semiconductor layers are formed between the first epitaxial source/drain feature and the second epitaxial source/drain feature. At least one dielectric spacer is formed between the two or more semiconductor layers after forming the first and second epitaxial source/drain features, wherein the dielectric spacer surrounds two opposite sides of the first epitaxial source/drain feature and the second epitaxial source/drain feature, and an interface between the dielectric spacer and each of the two opposite sides is a plane.

According to some embodiments of the present disclosure, a method of manufacturing a semiconductor device is provided as follows. A fin structure is formed on a substrate, the fin structure includes a plurality of first semiconductor layers and a plurality of second semiconductor layers alternately stacked to each other. A sacrificial gate structure is formed over a portion of the fin structure. The first semiconductor layers and the second semiconductor layers not covered by the sacrificial gate structure in a source/drain region of the fin structure are removed. An epitaxial source/drain feature is formed in the source/drain region. The second semiconductor layers are removed to form at least one cavity between the first semiconductor layers, and the cavity exposes side surfaces of the epitaxial source/drain feature. At least one dielectric spacer is formed on the side surfaces of the epitaxial source/drain feature and between the first semiconductor layers. The sacrificial gate structure is removed to expose the first semiconductor layers. A gate dielectric layer is formed to surround exposed surfaces of each of the first semiconductor layers. A gate electrode layer is formed on the gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a first epitaxial source/drain feature over a substrate;
forming a second epitaxial source/drain feature over the substrate;
forming two or more semiconductor layers between the first epitaxial source/drain feature and the second epitaxial source/drain feature; and
forming at least one dielectric spacer between the two or more semiconductor layers after forming the first and second epitaxial source/drain features, wherein the dielectric spacer surrounds two opposite sides of the first epitaxial source/drain feature and the second epitaxial source/drain feature.

2. The method of claim 1, further comprising forming a gate dielectric layer surrounding exposed surfaces of each of the two or more semiconductor layers.

3. The method of claim 2, further comprising forming at least one gate electrode layer between the two or more semiconductor layers, and the gate dielectric layer surrounding the gate electrode layer.

4. The method of claim 1, wherein an interface between the dielectric spacer and each of the two opposite sides is a plane.

5. The method of claim 4, wherein the plane is coplanar with side surfaces of the semiconductor layers.

6. The method of claim 4, wherein a side of the dielectric spacer away from the plane has a convex profile.

7. A method of manufacturing a semiconductor device, comprising:
forming a fin structure on a substrate, the fin structure including a plurality of first semiconductor layers and a plurality of second semiconductor layers alternately stacked to each other;
forming a sacrificial gate structure over a portion of the fin structure;
removing the first semiconductor layers and the second semiconductor layers not covered by the sacrificial gate structure in a source/drain region of the fin structure;
forming an epitaxial source/drain feature in the source/drain region;
removing the sacrificial gate structure;
removing the second semiconductor layers to form at least one cavity between the first semiconductor layers, the cavity exposing side surfaces of the epitaxial source/drain feature and an upper surface and a lower surface of the first semiconductor layers;
forming at least one dielectric spacer on the side surfaces of the epitaxial source/drain feature and between the first semiconductor layers;
forming a gate dielectric layer to surround exposed surfaces of each of the first semiconductor layers; and
forming a gate electrode layer on the gate dielectric layer.

8. The method of claim 7, wherein the dielectric spacer surrounds two opposite sides of the epitaxial source/drain feature, and an interface between the dielectric spacer and each of the two opposite sides is a plane.

9. The method of claim 8, wherein the plane is coplanar with side surfaces of the first semiconductor layers.

10. The method of claim 8, wherein a side of the dielectric spacer away from the plane has a convex profile.

11. The method of claim 7, wherein the dielectric spacer is formed in the cavity after forming the epitaxial source/drain feature.

12. The method of claim 7, wherein forming the dielectric spacer comprises:
forming an inhibitor material layer in the cavity, the inhibitor material layer covering the exposed surfaces of the first semiconductor layers and the side surfaces of the epitaxial source/drain feature;
etching the inhibitor material layer to remove a part of the inhibitor material layer deposited on side surfaces of the epitaxial source/drain feature;
forming the dielectric spacer on the side surfaces of the epitaxial source/drain feature but not on surfaces of the first semiconductor layers covered by the inhibitor material layer; and
removing the inhibitor material layer to expose the surfaces of the first semiconductor layers.

13. The method of claim 12, wherein a thickness of the inhibitor material layer on the first semiconductor layers is greater than a thickness of the inhibitor material layer on the epitaxial source/drain feature.

14. The method of claim 12, wherein the inhibitor material layer is formed of an organic compound.

15. The method of claim 12, wherein a deposition of the inhibitor material layer on the first semiconductor layers has a selectivity relative to a deposition of the inhibitor material layer on the epitaxial source/drain feature.

16. The method of claim 7, wherein the dielectric spacer is an oxygen-containing silicon material, wherein the silicon content is between 25% and 40%.

17. The method of claim 7, wherein the dielectric spacer is a silicon material containing oxygen and carbon, wherein the silicon content is between 25% and 35%, and the carbon content is between 0.1 and 15%.

18. A semiconductor device, comprising:
a first epitaxial source/drain feature;
a second epitaxial source/drain feature;
two or more semiconductor layers electrically connected between the first epitaxial source/drain feature and the second epitaxial source/drain feature; and
at least one dielectric spacer located between the two or more semiconductor layers, the dielectric spacer surrounds two opposite sides of the first epitaxial source/drain feature and the second epitaxial source/drain feature, and an interface between the dielectric spacer and each of the two opposite sides is a plane, wherein the dielectric spacer is selectively formed on the two opposite sides of the first and second epitaxial source/drain feature.

19. The semiconductor device of claim 18, wherein the plane is coplanar with the side surfaces of the semiconductor layers.

20. The semiconductor device of claim 18, wherein a side of the dielectric spacer away from the plane has a convex profile.
